(19) United States
(12) Patent Application Publication
(10) Pub. No.: US 2022/0190061 A1
(43) Pub. Date: Jun. 16, 2022

(54) DISPLAY PANEL

(71) Applicant: Samsung Display Co., Ltd., Yongin-si (KR)

(72) Inventors: Jong In Baek, Yongin-si (KR); Seong Jun Lee, Yongin-si (KR); Ja Seung Ku, Yongin-si (KR); Wang Jo Lee, Yongin-si (KR)

(21) Appl. No.: 17/491,918

(22) Filed: Oct. 1, 2021

(30) Foreign Application Priority Data
Dec. 15, 2020 (KR) 10-2020-0175870

(51) Int. Cl. H01L 27/32

(52) U.S. Cl. CPC H01L 27/3227; H01L 27/323; H01L 27/322

(57) ABSTRACT

A display panel includes: a base layer including an emission area and a sensor area; a pixel circuit disposed on the emission area of the base layer; illuminance sensors disposed on the sensor area of the base layer, each of the illuminance sensors including a light receiving element overlapping the sensor area, the light receiving element disposed to be adjacent to the pixel circuit; light emitting elements disposed on the pixel circuit, each of the light emitting elements including a light emitting layer overlapping the emission area; a black matrix including openings overlapping the light emitting layer; and a color filter disposed on the light emitting elements and the black matrix.

### CROSS-REFERENCE TO RELATED APPLICATION

This application claims priority from and the benefit of Korean Patent Application No. 10-2020-0175870, filed Dec. 15, 2020, which is hereby incorporated by reference for all purposes as if fully set forth herein.

### BACKGROUND

### Field

Implementations of the invention relate generally to a display device, and more specifically, to a display panel including an illuminance sensor.

### Discussion of the Background

A portable device (hereinafter, referred to as an electronic device) such as a wearable device, a smart phone, and a video playback device includes a display device that displays an image. In recent years, in order to improve the visibility of the image and reduce power consumption, a technology that detects ambient illuminance and automatically controls the brightness of the image according to the detected ambient illuminance has been used. For example, an illuminance sensor for sensing illuminance may be exposed outside the electronic device or may be mounted outside the display device.

In addition, studies on the laminated structure of the display device are also in progress to reduce the thickness of the display panel, display device, and electronic device.

The above information disclosed in this Background section is only for understanding of the background of the inventive concepts, and, therefore, it may contain information that does not constitute prior art.

### SUMMARY

Display devices with a display panel constructed according to the principles of the invention are capable of reducing and minimizing the thickness of the display panel by disposing an illuminance sensor and a pixel circuit of the display panel on the same layer.

Further, the display devices constructed according to the principles of the invention are capable of increasing the amount (e.g., intensity) of external light incident on the illuminance sensor such that the reliability of detecting illuminance may be improved.

Additional features of the inventive concepts will be set forth in the description which follows, and in part will be apparent from the description, or may be learned by practice of the inventive concepts.

According to an aspect of the invention, a display panel includes: a base layer including an emission area and a sensor area; a pixel circuit disposed on the base layer; illuminance sensors disposed on the sensor area of the base layer, each of the illuminance sensors including a light receiving element overlapping the sensor area, the light receiving element disposed to be adjacent to the pixel circuit; light emitting elements disposed on the pixel circuit, each of the light emitting elements including a light emitting layer overlapping the emission area; a black matrix disposed on the light emitting element, the black matrix including openings overlapping the light emitting layer; and a color filter disposed on the light emitting elements and the black matrix.

Each of the illuminance sensors may further include: a sensor transistor connected to the light receiving element; and a capacitor connected to the light receiving element and configured to store a detection value of the light receiving element.

The sensor transistor may include: a first active pattern disposed on the base layer; a first gate electrode overlapping the first active pattern and disposed on a gate insulating layer covering the first active pattern; and a first source electrode and a first drain electrode disposed on an interlayer insulating layer covering the first gate electrode and a first insulating layer, and contacting the first active pattern through contact holes penetrating the first insulating layer, the interlayer insulating layer, and the gate insulating layer.

The pixel circuit may further include: a pixel transistor connected to each of the light emitting elements, and wherein the pixel transistor may include: a second active pattern disposed on a same layer, on which the first active pattern is disposed; a second gate electrode disposed on a same layer, on which the first gate electrode disposed; and a second source electrode and a second drain electrode disposed on a same layer, on which the first source electrode is disposed, and contacting the second active pattern through contact holes penetrating the first insulating layer, the interlayer insulating layer, and the gate insulating layer.

Each of the light emitting elements may further include: a first electrode and a second electrode disposed on a second insulating layer on the pixel circuit, and wherein the light emitting layer may be interposed between the first electrode and the second electrode.

The display panel may further include a bank layer disposed on the second insulating layer to expose an upper surface of the first electrode, the bank layer partitioning the emission area.

The bank layer may overlap the black matrix and is disposed between the emission area and the sensor area in a plan view.

The color filter may include a first color filter overlapping a light receiving element of a first illuminance sensor among the illuminance sensors and a second color filter overlapping a first light emitting element among the light emitting elements, the first light emitting element adjacent to one side of the first illuminance sensor in a first direction, and the first color filter may be different from the second color filter.

The color filter may further include a third color filter overlapping a light receiving element of a second illuminance sensor among the illuminance sensors and a fourth color filter overlapping a second light emitting element among the light emitting elements, the second light emitting element adjacent to one side of the second illuminance sensor in the first direction, and the third color filter may be same as the fourth color filter.

The display panel may further include a transparent insulating layer overlapping a light receiving element of a third illuminance sensor among the illuminance sensors and covering a portion of the black matrix.

The black matrix and the bank layer may overlap a light receiving element of a fourth illuminance sensor among the illuminance sensors.

A size of the emission area corresponding to the first light emitting element may be smaller than a size of the emission area corresponding to a light emitting element that emits light in a same color as that of light emitted by the first light emitting element and may not be adjacent to the illuminance sensors.

The pixel circuit connected to the first light emitting element and the first illuminance sensor may be connected to a same scan line.

The second electrode may extend to overlap the sensor area.

The second electrode may include an opening overlapping the sensor area.

The light receiving element may include: a conductive layer disposed on the interlayer insulating layer; a semiconductor layer disposed on the conductive layer; and a transparent conductive layer disposed on the semiconductor layer and overlapping the sensor area.

Each of the illuminance sensors may further include a bias electrode disposed on the first insulating layer, the bias electrode connected to the transparent conductive layer by passing through the first insulating layer.

The capacitor may include a capacitor electrode pattern disposed on a same layer, on which the first gate electrode is disposed, and overlapping the first active pattern.

The bias electrode may pass through the interlayer insulating layer and the first insulating layer, and may be connected to the capacitor electrode pattern.

The display panel may further include a touch sensor layer disposed between the light emitting elements and the black matrix.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the inventive concepts, and are incorporated in and constitute a part of this specification, illustrate exemplary embodiments of the inventive concepts, and, together with the description, serve to explain principles of the inventive concepts.

FIG. 1 is a block diagram of an embodiments of a display device constructed according to the principles of the invention.

FIG. 2 is a schematic plan view of an embodiment of a display panel included in the display device of FIG. 1.

FIG. 3 is a circuit diagram of an embodiment of a pixel and an illuminance sensor included in the display panel of FIG. 2.

FIG. 4 is a cross-sectional view taken along lines I-I′ of FIG. 2 illustrating an example of an area of the display panel of FIG. 2.

FIG. 5 is a circuit diagram of another embodiment of the illuminance sensor of FIG. 3.

FIG. 6 is a cross-sectional view taken along lines II-II′ of FIG. 2 illustrating an example of an area of the display panel of FIG. 2.

FIG. 7 is a cross-sectional view taken along lines III-III′ of FIG. 2 illustrating an example of an area of the display panel of FIG. 2.

FIG. 8 is a cross-sectional view taken along lines IV-IV′ of FIG. 2 illustrating an example of an area of the display panel of FIG. 2.

FIG. 9 is a cross-sectional view taken along lines I-I′ of FIG. 2 illustrating another example of an area of the display panel of FIG. 2.

FIG. 10 is a plan view of an example of a second electrode of a light emitting element included in the display panel of FIG. 9.

FIG. 11 is a schematic plan view of another embodiment of the display panel included in the display device of FIG. 1.

FIG. 12 is a schematic plan view of another embodiment of the display panel included in the display device of FIG. 1.

### DETAILED DESCRIPTION

In the following description, for the purposes of explanation, numerous specific details are set forth in order to provide a thorough understanding of various exemplary embodiments or implementations of the invention. As used herein “embodiments” and “implementations” are interchangeable words that are non-limiting examples of devices or methods employing one or more of the inventive concepts disclosed herein. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an exemplary embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, preferred embodiments will be described in more detail with reference to the accompanying drawings.

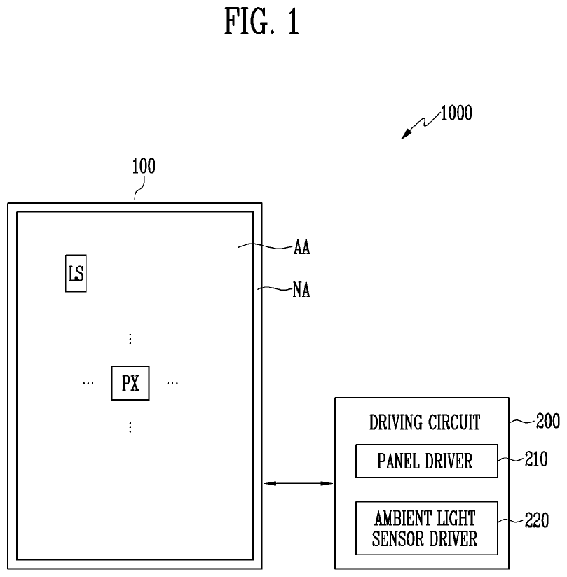

FIG. 1 is a block diagram illustrating a display device according to embodiments.

For convenience, in FIG. 1, a display panel 100 and a driving circuit 200 are separately shown, but embodiments are not limited thereto. More specifically, all or part of the driving circuit 200 may be integrally implemented on the display panel 100.

Referring to FIG. 1, a display device 1000 may include the display panel 100 and the driving circuit 200.

The display device 1000 may be implemented as a self-light emitting display device including a plurality of self-light emitting elements. For example, the display device 1000 may be an organic light emitting display device including organic light emitting elements, a display device including inorganic light emitting elements, or a display device including light emitting elements composed of a combination of inorganic and organic materials. However, this is an example, and the display device 1000 may be implemented as a liquid crystal display device, a plasma display device, a quantum dot display device, or the like.

The display device 1000 may be a flat panel display device, a flexible display device, a curved display device, a foldable display device, or a bendable display device. In addition, the display device 1000 may be applied to a transparent display device, a head-mounted display device, a wearable display device, or the like.

The display panel 100 may include a display area AA and a non-display area NA. The display area AA may include a plurality of pixels PX and illuminance sensors LS. According to an embodiment, each of the pixels PX may include at least one light emitting element, and a portion from which light is emitted by the light emitting element may be defined as an emission area.

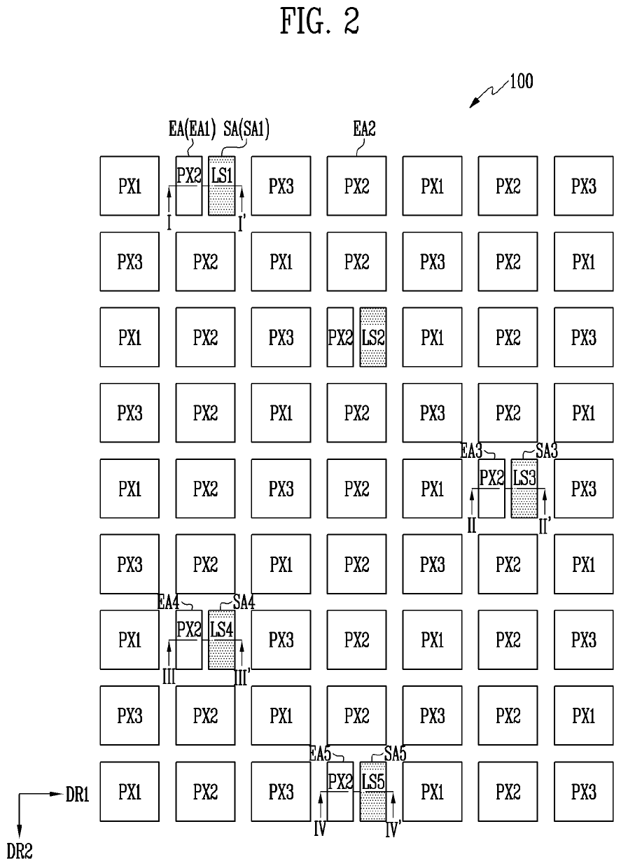

In an embodiment, the display area AA may include a sensor area. The sensor area may correspond to a portion where a light receiving element of an illuminance sensor LS is positioned. Illuminance may be detected by detecting external light supplied to the sensor area. The arrangement relationship, the stacked structure, and the like of the illuminance sensor LS and the pixel PX will be described in detail below with reference to FIG. 2.

In an embodiment, the illuminance sensor LS and a pixel circuit of the pixel PX may be disposed on the same layer, e.g., on the buffer layer BF or the base layer BL.

The non-display area NA may be an area disposed around the display area AA.

According to embodiments, the non-display area NA may mean the remaining area on the display panel 100 except for the display area AA.

In an embodiment, the non-display area NA may include a wiring area, a pad area, and various dummy areas.

The driving circuit 200 may drive the display panel 100. For example, the driving circuit 200 may output a data signal corresponding to image data to the display panel 100, or may output a driving signal for driving the illuminance sensor LS and receive a detection signal from the illuminance sensor LS. The driving circuit 200 may detect external illuminance using the detection signal.

In an embodiment, the driving circuit 200 may include a panel driver 210 and an illuminance sensor driver 220. For convenience, in FIG. 1, the panel driver 210 and the illuminance sensor driver 220 are separately shown, but embodiments are not limited thereto. For example, at least a portion of the illuminance sensor driver 220 may be integrated with the panel driver 210 or may be operated in conjunction with the panel driver 210.

The panel driver 210 may supply the data signal corresponding to the image data to the pixels PX while sequentially scanning the pixels PX in the display area AA. Accordingly, the display panel 100 may display an image corresponding to the image data.

In an embodiment, the panel driver 210 may supply a scan signal to the pixels PX and the illuminance sensors LS. The scan signal may be provided to write data to the pixels PX and outputting the detection signal from the illuminance sensor LS.

The detection signal may be supplied to the illuminance sensor driver 220. The illuminance sensor driver 220 may calculate a value of ambient illuminance by analyzing the detection signal.

FIG. 2 is a diagram conceptually illustrating an example of a display panel included in the display device of FIG. 1.

Referring to FIGS. 1 and 2, the display panel 100 may include a plurality of pixels PX1, PX2, and PX3 and a plurality of illuminance sensors LS1, LS2, LS3, LS4, and LS5.

The first pixel PX1, the second pixel PX2, and the third pixel PX3 may emit a first color light, a second color light, and a third color light, respectively. In an embodiment, the first color light, the second color light, and the third color light may be different color lights, and may be one of red light, green light, and blue light. For example, in a first pixel row (e.g., odd-numbered pixel rows) controlled by a first scan line, the pixels PX1, PX2, and PX3 may be arranged in the order of a red pixel, a green pixel, a blue pixel, and a green pixel in a first direction DR1. In a second pixel row (e.g., even pixel rows) controlled by a second scan line, the pixels PX1, PX2, and PX3 may be arranged in the order of a blue pixel, a green pixel, a red pixel, and a green pixel in the first direction DR1.

The arrangement of the pixels in the first pixel row and the arrangement of the pixels in the second pixel row may be alternately repeated in a second direction DR2 to form, e.g., a pentile pixel structure. However, this is an example, and embodiments are not limited thereto.

On the other hand, in FIG. 2, except for a portion in which the illuminance sensors LS1, LS2, LS3, LS4, and LS5 are disposed, the first, second, and third pixels PX1, PX2, and PX3 are shown to have the same area, but embodiments are not limited thereto. For example, a pixel emitting the blue light may have a larger area than other pixels. In the embodiments, the size (e.g., area) of a pixel may be understood as an area of an emission area of the corresponding pixel, e.g., in a plan view.

In an embodiment, each of the illuminance sensors LS1, LS2, LS3, LS4, and LS5 may be disposed between predetermined pixels in a plan view. For example, each of the illuminance sensors LS1, LS2, LS3, LS4, and LS5 may be disposed on one side of each of predetermined second pixels PX2. Here, in order to minimize deterioration of image quality, the number of illuminance sensors may be smaller than the number of pixels. However, this is an example, and the position and number of the illuminance sensors LS1, LS2, LS3, LS4, and LS5 are not limited to the structure shown in FIG. 2.

The first, second, third, fourth, and fifth illuminance sensors LS1, LS2, LS3, LS4, and LS5 may detect the amount (e.g., intensity) of different color lights. In an embodiment, each of the first, second, and third illuminance sensors LS1, LS2, and LS3 may detect the amount (e.g., intensity) of one of the red light, the green light, and the blue light. The illuminance sensor driver 220 may calculate illuminance by combining detection values (e.g., detected intensity) supplied from the first, second, and third illuminance sensors LS1, LS2, and LS3.

The fourth illuminance sensor LS4 may detect the amount (e.g., intensity) of white light. The fifth illuminance sensor LS5 may detect the amount (e.g., intensity) of light when no external light is incident (e.g., black light). The fourth illuminance sensor LS4 and the fifth illuminance sensor LS5 may be included to correct a detection error value (e.g., detection error intensity) due to an error value (e.g., thermal current, dark current, and the like) of the illuminance sensors. For example, the fourth illuminance sensor LS4 and the fifth illuminance sensor LS5 may supply reference values as a reference for the detection values supplied from the first, second, and third illuminance sensors LS1, LS2, and LS3.

The illuminance sensor driver 220 may calculate a more accurate illuminance value by applying the detection values supplied from the fourth illuminance sensor LS4 and the fifth illuminance sensor LS5 to the detection values supplied from the first, second, and third illuminance sensors LS1, LS2, and LS3.

However, this is an example, and at least one of the fourth illuminance sensor LS4 and the fifth illuminance sensor LS5 may be omitted.

In an embodiment, each of the illuminance sensors LS1, LS2, LS3, LS4, and LS5 may be formed in a portion of the emission area in which a pixel is to be formed. For example, as shown in FIG. 2, the size (e.g., area) of an emission area EA1 (e.g., a first emission area) of the second pixel PX2 adjacent to the first illumination sensor LS1 may be smaller than the size (e.g., area) of an emission area EA2 (or a second emission area) of other second pixel PX2 not adjacent to the illumination sensors. The size (e.g., area) of the sensor area SA overlapping the light receiving element of the first illuminance sensor LS1 may be smaller than the size (e.g., area) of the second emission area EA2 of other second pixel PX2 not adjacent to the illumination sensors. For example, the width of the sensor area SA overlapping the light receiving element of the first illuminance sensor LS1 in the second direction DR2 may be substantially same as the width of the second emission area EA2 of the other second pixel PX2 not adjacent to the illumination sensors in the second direction DR2, e.g., in a plan view. For example, the width of the sensor area SA overlapping the light receiving element of the first illuminance sensor LS1 in the first direction DR1 may be smaller than the width of the second emission area EA2 of the other second pixel PX2 not adjacent to the illumination sensors in the first direction DR1, e.g., in a plan view.

Since this is an example, the sizes (e.g., areas) of the emission areas EA1 and EA2 and the size (e.g., area) of the sensor area SA are not limited thereto.

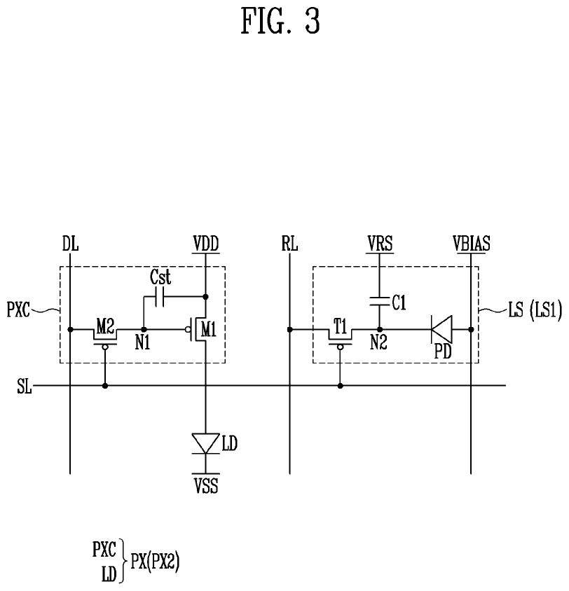

FIG. 3 is a circuit diagram illustrating an example of a pixel and an illuminance sensor included in the display panel of FIG. 2.

Referring to FIGS. 2 and 3, the pixel PX may include a pixel circuit PXC and a light emitting element LD, and the illuminance sensor LS may include a light receiving element PD, a sensor transistor T1, and a capacitor C1.

For example, FIG. 3 shows a circuit diagram of the second pixel PX2 and the first illumination sensor LS1 adjacent to the second pixel PX2.

The pixel PX may include the pixel circuit PXC and the light emitting element LD connected thereto. The pixel circuit PXC may include a first pixel transistor M1, a second pixel transistor M2, a storage capacitor Cst, and the light emitting element LD.

The first pixel transistor M1 and the second pixel transistor M2 may be P-type transistors (e.g., PMOS transistors), but embodiments are not limited thereto. For example, at least one of the first pixel transistor M1 and the second pixel transistor M2 may be implemented as an N-type transistor (e.g., NMOS transistor). Also, the pixel circuit PXC may further include other transistors in addition to the first pixel transistor M1 and the second pixel transistor M2. For example, the pixel circuit PXC may include various circuit configurations such as a known 7T1C structure including seven transistors and one capacitor.

The first pixel transistor M1 (e.g., a driving transistor) may be connected between a first power source line, to which a voltage of a first power source VDD is applied, and an anode electrode of the light emitting element LD. The first pixel transistor M1 may include a gate electrode connected to a first node N1.

The second pixel transistor M2 (e.g., a switching transistor) may be connected between a data line DL and the first node N1. The second pixel transistor M2 may include a gate electrode connected to a scan line SL.

The second pixel transistor M2 may be turned on in response to a scan signal provided through the scan line SL, and transmit a data signal provided through the data line DL to the first node N1. For example, the scan signal may be a pulse signal having a turn-on voltage level for turning on the second pixel transistor M2.

The storage capacitor Cst may be connected between the first node N1 and the first power source line (e.g., the power source line to which the voltage of the first power source VDD is applied). The storage capacitor Cst may temporarily store the data signal applied to the first node N1. In this case, the first pixel transistor M1 may control the amount of driving current flowing from the first power source line to the light emitting element LD in response to the data signal stored in the storage capacitor Cst.

The light emitting element LD (e.g., light emitting diode) may include the anode electrode connected to the first pixel transistor M1 and a cathode electrode connected to a second power source line to which a voltage of a second power source VSS is applied. For example, the light emitting element LD may be an organic light emitting element, an inorganic light emitting element, or a light emitting element composed of a combination of organic and inorganic materials. The light emitting element LD may emit light with a luminance corresponding to the driving current (e.g., the amount of driving current).

In an embodiment, the illuminance sensor LS may include the light receiving element PD, the sensor transistor T1, and the capacitor C1.

In FIG. 3, one sensor transistor T1 and one light receiving element PD are shown for convenience of description, but embodiments are not limited thereto. The illuminance sensor LS may include one light receiving element PD and two or more transistors.

The light receiving element PD may be connected between a second node N2 and a third power source line through which a bias power source VBIAS is transmitted. In an embodiment, the light receiving element PD may be a photodiode including a semiconductor layer in which the amount of current changes according to the amount (e.g., intensity) of light. However, this is an example, and the light receiving element PD may be implemented as a phototransistor, a photomultiplier tube, or the like.

The bias power source VBIAS may be a power source that supplies a constant voltage that is a reference power voltage for generating a current in the light receiving element PD.

The sensor transistor T1 may be connected between the second node N2 and a readout line RL. The sensor transistor T1 may include a gate electrode connected to the scan line SL.

The sensor transistor T1 may be turned on in response to the scan signal provided through the scan line SL, and may transmit the detection value (voltage and/or current) generated by the light receiving element PD to the readout line RL.

In an embodiment, as shown in FIG. 3, the scan line SL may be commonly connected to the gate electrode of the second pixel transistor M2 and the gate electrode of the sensor transistor T1. Accordingly, the structure of a backplane of the display device 1000 in which the illuminance sensor LS and the pixel circuit PXC are formed may be simplified.

However, this is an example, and the sensor transistor T1 and the second pixel transistor M2 may be connected to different scan lines.

The capacitor C1 may be connected between a fourth power source line, through which a reset power source VRS is transmitted, and the second node N2. The capacitor C1 may temporarily store the detection value (e.g., a voltage or charge corresponding to light intensity) applied to the second node N2. The reset power source VRS may be a constant voltage source serving as a reference voltage for the amount of charge stored in the capacitor C1.

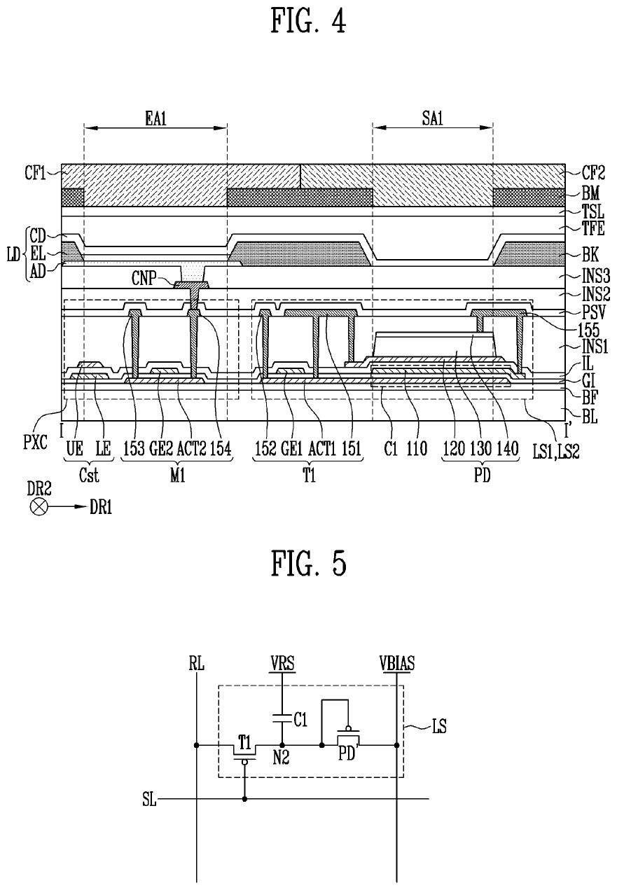

FIG. 4 is a cross-sectional view taken along lines I-I′ of FIG. 2 illustrating an example of an area of the display panel of FIG. 2.

Referring to FIGS. 1, 2, 3, and 4, the pixel PX may include the pixel circuit PXC and the light emitting element LD, and the illuminance sensor LS may include the light receiving element PD, the sensor transistor T1, and the capacitor C1.

A base layer BL may be made of an insulating material such as glass, resin, or the like. In addition, the base layer BL may be formed of a material having flexibility to be bent or folded, and may have a single layer structure or a multilayer structure.

A buffer layer BF may be formed on the base layer BL. The buffer layer BF may prevent impurities from diffusing or permeating into the transistors T1 and M1. The buffer layer BF may be omitted according to the material and process conditions of the base layer BL.

A first active pattern ACT1 and a second active pattern ACT2 may be provided on the buffer layer BF. The first active pattern ACT1 and the second active pattern ACT2 may be formed of a semiconductor material. Each of the first and second active patterns ACT1 and ACT2 may include a source region, a drain region, and a channel region provided between the source region and the drain region.

A gate insulating layer GI may be provided on the first active pattern ACT1 and the second active pattern ACT2. The gate insulating layer GI may be an inorganic insulating layer made of an inorganic material.

A first gate electrode GE1, a second gate electrode GE2, and a capacitor electrode pattern 110 may be provided on the gate insulating layer GI. Also, a capacitor lower electrode LE may be further provided on the gate insulating layer GI.

The first gate electrode GE1 may be formed to cover a region corresponding to the channel region of the first active pattern ACT1. The second gate electrode GE2 may be formed to cover a region corresponding to the channel region of the second active pattern ACT2.

The capacitor electrode pattern 110 may overlap a portion of the first active pattern ACT1. The capacitor electrode pattern 110, the portion of the first active pattern ACT1 overlapping therewith, and the gate insulating layer GI interposed therebetween may constitute the capacitor C1.

The first gate electrode GE1, the second gate electrode GE2, the capacitor electrode pattern 110, and the capacitor lower electrode LE may be made of a conductive material such as metal. For example, the first gate electrode GE1, the second gate electrode GE2, the capacitor electrode pattern 110, and the capacitor lower electrode LE may be made of at least one of metals such as gold (Au), silver (Ag), aluminum (Al), molybdenum (Mo), chromium (Cr), titanium (Ti), nickel (Ni), neodymium (Nd), and copper (Cu), or an alloy thereof. In addition, the first gate electrode GE1, the second gate electrode GE2, the capacitor electrode pattern 110, and the capacitor lower electrode LE may be formed as a single layer or multiple layers in which two or more of metals and alloys are stacked.

An interlayer insulating layer IL may be provided on the first gate electrode GE1, the second gate electrode GE2, the capacitor electrode pattern 110, and the capacitor lower electrode LE. The interlayer insulating layer IL may be an inorganic insulating layer made of an inorganic material such as poly-siloxane, silicon nitride, silicon oxide, silicon oxynitride, and the like.

A capacitor upper electrode UE may be provided on the interlayer insulating layer IL. In an embodiment, a conductive layer 120 of the light receiving element PD may be further provided on the interlayer insulating layer IL. The conductive layer 120 may overlap a first sensor area SA1.

The capacitor upper electrode UE and the conductive layer 120 may include the same metal material. For example, the capacitor upper electrode UE and the conductive layer 120 may be made of at least one of metals such as gold (Au), silver (Ag), aluminum (Al), molybdenum (Mo), chrome (Cr), titanium (Ti), nickel (Ni), neodymium (Nd), and copper (Cu), or an alloy thereof. In addition, the capacitor upper electrode UE and the conductive layer 120 may be formed as a single layer, but embodiments are not limited thereto, and may be formed as multiple layers in which two or more of metals and alloys are stacked.

The capacitor lower electrode LE, the capacitor upper electrode UE, and the interlayer insulating layer IL interposed between the capacitor lower electrode LE and the capacitor upper electrode UE may constitute the storage capacitor Cst.

A semiconductor layer 130 may be disposed on the conductive layer 120. In an embodiment, the semiconductor layer 130 may include an upper doped region, a lower doped region, and a channel region between the doped regions. For example, the lower doped region may be an n-type doped region, and the upper doped region may be a p-type doped region. However, this is an example, and the properties of the doped regions may be changed.

In an embodiment, the semiconductor layer 130 may include an inorganic semiconductor. For example, the semiconductor layer 130 may include single crystal silicon, polycrystalline silicon, or metal oxide. Alternatively, the semiconductor layer 130 may include an organic semiconductor.

In an embodiment, the semiconductor layer 130 may include the upper doped region and the channel region, and the conductive layer 120 may function as the lower doped region.

A transparent conductive layer 140 may be provided on the semiconductor layer 130. The transparent conductive layer 140 may overlap the first sensor area SA1. The transparent conductive layer 140 may include a transparent conductive material to receive the external light. For example, the transparent conductive layer 140 may be made of indium tin oxide (ITO), indium zinc oxide (IZO), zinc oxide (ZnO), indium tin zinc oxide (ITZO), or the like.

The conductive layer 120, the semiconductor layer 130, and the transparent conductive layer 140 may constitute the light receiving element PD.

A first insulating layer INS1 may be provided on the capacitor upper electrode UE and the light receiving element PD. The first insulating layer INS1 may be an inorganic insulating layer made of an inorganic material such as poly-siloxane, silicon nitride, silicon oxide, silicon oxynitride, or the like. The first insulating layer INS1 made of the inorganic material may block, absorb, or filter ultraviolet rays which may reduce the stability of the light receiving element PD without significantly affecting the photoelectric conversion of the light receiving element PD.

A first source electrode 151, a first drain electrode 152, a second source electrode 153, and a second drain electrode 154 may be provided on the first insulating layer INS1. In FIGS. 3 and 4, the transistors M1 and T1 are shown as P-type transistors, but the source electrode and the drain electrode may vary according to the type of the transistors and the like.

The first source electrode 151 and the first drain electrode 152 may respectively contact the source region and the drain region of the first active pattern ACT1 through contact holes formed in the first insulating layer INS1, the interlayer insulating layer IL, and the gate insulating layer GI. The first source electrode 151, the first drain electrode 152, the first gate electrode GE1, and the first active pattern ACT1 may constitute the sensor transistor T1.

The second source electrode 153 and the second drain electrode 154 may respectively contact the source region and the drain region of the second active pattern ACT2 through contact holes formed in the first insulating layer INS1, the interlayer insulating layer IL, and the gate insulating layer GI. The second source electrode 153, the second drain electrode 154, the second gate electrode GE2, and the second active pattern ACT2 may constitute the first pixel transistor M1.

The source electrodes 151 and 153 and the drain electrodes 152 and 154 may be made of a conductive material such as metal. For example, the source electrodes 151 and 153 and the drain electrodes 152 and 154 may be made of at least one of metals such as gold (Au), silver (Ag), aluminum (Al), molybdenum (Mo), chromium (Cr), titanium (Ti), nickel (Ni), neodymium (Nd), and copper (Cu), or an alloy thereof.

In an embodiment, the first source electrode 151 may further contact the conductive layer 120 through a contact hole formed in the first insulating layer INS1. Accordingly, the sensor transistor T1 may be connected to the light receiving element PD.

In an embodiment, the illuminance sensor LS may further include a bias electrode 155 through which a voltage of the bias power source VBIAS is transmitted. The bias electrode 155 may be provided on the first insulating layer INS1. The bias electrode 155 may pass through the first insulating layer INS1 and may be connected to the transparent conductive layer 140. The bias electrode 155, the source electrodes 151 and 153, and the drain electrodes 152 and 154 may be formed of the same material in the same process.

In an embodiment, the bias electrode 155 may pass through the first insulating layer INS1 and the interlayer insulating layer IL and may be connected to the capacitor electrode pattern 110. In this case, the reset power source VRS and the bias power source VBIAS may have substantially the same voltage level.

A passivation layer PSV may be provided on the source electrodes 151 and 153, the drain electrodes 152 and 154, and the bias electrode 155. The passivation layer PSV may be an inorganic insulating layer made of an inorganic material such as poly-siloxane, silicon nitride, silicon oxide, silicon oxynitride, or the like.

A second insulating layer INS2 may be provided on the passivation layer PSV. In an embodiment, the second insulating layer INS2 may be an organic insulating layer made of an organic material including an organic insulating material such as a poly-acrylic compound, a polyimide compound, a fluorine-based carbon compound such as Teflon, a benzocyclobutene compound, and the like.

A connection pattern CNP may be provided on the second insulating layer INS2. The connection pattern CNP may be connected to the second drain electrode 154 through a contact hole penetrating the second insulating layer INS2 and the passivation layer PSV. The connection pattern CNP may be made of at least one of metals such as gold (Au), silver (Ag), aluminum (Al), molybdenum (Mo), chromium (Cr), titanium (Ti), nickel (Ni), neodymium (Nd), and copper (Cu), or an alloy thereof.

A third insulating layer INS3 may be provided on the connection pattern CNP. The third insulating layer INS3 may be an organic insulating layer made of an organic material including an organic insulating material such as a poly-acrylic compound, a polyimide compound, a fluorine-based carbon compound such as Teflon, a benzocyclobutene compound, and the like. Alternatively, the third insulating layer INS3 may be an inorganic insulating layer made of an inorganic material.

A first electrode AD may be provided on the third insulating layer INS3. The first electrode AD may be connected to the connection pattern CNP through a contact hole penetrating the third insulating layer INS3. Here, the first electrode AD may be used as one of the anode electrode and the cathode electrode of the light emitting element LD according to embodiments.

FIG. 4 shows a case in which the passivation layer PSV, the second insulating layer INS2, and the third insulating layer INS3 are provided. However, embodiments are not limited thereto, and the arrangement structure of the insulating layers may vary.

For example, only the passivation layer PSV may be provided on the source and drain electrodes 151, 152, 153, and 154, and the first electrode AD may be provided on the passivation layer PSV. Alternatively, only the passivation layer PSV and the second insulating layer INS2 may be provided on the source and drain electrodes 151, 152, 153, and 154, and the first electrode AD may be provided on the second insulating layer INS2. In this case, the connection pattern CNP may be omitted and the first electrode AD may be directly connected to the second drain electrode 154.

The first electrode AD may be made of a metal layer such as Ag, Mg, Al, Pt, Pd, Au, Ni, Nd, Ir, Cr, or alloys thereof, or may be made of indium tin oxide (ITO), indium zinc oxide (IZO), zinc oxide (ZnO), indium tin zinc oxide (ITZO), or the like.

A bank layer BK (e.g., a pixel defining layer) for partitioning the first emission area EA1 to correspond to each pixel PX may be provided on the third insulating layer INS3 on which the first electrode AD and the like are formed. The bank layer BK may be an organic insulating layer made of an organic material including acrylic resin, epoxy resin, phenolic resin, polyamide resin, polyimide resin, and the like.

In addition, the bank layer BK may include a light absorbing material or may be coated with a light absorbing agent to absorb light incident from the outside. For example, the bank layer BK may include a carbon-based black pigment. However, embodiments are not limited thereto, and the bank layer BK may include an opaque metal material having a high light absorption rate such as chromium (Cr), molybdenum (Mo), an alloy of molybdenum and titanium (MoTi), tungsten (W), vanadium (V), niobium (Nb), tantalum (Ta), manganese (Mn), cobalt (Co), or nickel (Ni).

The bank layer BK may expose the upper surface of the first electrode AD and may protrude from the third insulating layer INS3 along the periphery of the pixel PX.

In an embodiment, the bank layer BK may be disposed between the first emission area EA1 and the first sensor area SA1. For example, the bank layer BK may include openings corresponding to the first emission area EA1 and the first sensor area SA1. For example, an opening of the bank layer BK corresponding to the first sensor area SA1 may overlap the upper surface of the light receiving element PD.

A light emitting layer EL may be provided in the first emission area EA1 surrounded by the bank layer BK. The light emitting layer EL may be provided as a single layer, or may be provided as multiple layers including various functional layers. In an embodiment, the light emitting layer EL may be formed of an organic light emitting layer. When the light emitting layer EL is provided in the multiple layers, a hole injection layer (HIL), a hole transport layer (HTL), an emission layer (EML), an electron transport layer (ETL), an electron injection layer (EIL), and the like may be stacked in a single or complex structure.

A second electrode CD may be provided on the light emitting layer EL. The second electrode CD may be provided for each pixel PX, or may be shared by a plurality of pixels. For example, the second electrode CD may be integrally formed on the display area AA.

The second electrode CD may be used as either the anode electrode or the cathode electrode according to embodiments. When the first electrode AD is the anode electrode, the second electrode CD may be used as the cathode electrode. When the first electrode AD is the cathode electrode, the second electrode CD may be used as the anode electrode.

The second electrode CD may be formed of a metal layer such as Ag, Mg, Al, Pt, Pd, Au, Ni, Nd, Ir, Cr, or the like, or a transparent conductive layer such as ITO, IZO, ZnO, ITZO, or the like. In an embodiment, the second electrode CD may be formed of multiple layers of a double layer or more including a metal thin film layer, for example, a triple layer of ITO/Ag/ITO.

The first electrode AD, the light emitting layer EL, and the second electrode CD may constitute the light emitting element LD.

An encapsulation layer TFE may be provided on the second electrode CD. The encapsulation layer TFE may be formed of a single layer, or may be formed of multiple layers. In an embodiment, the encapsulation layer TFE may have a stacked structure in which an inorganic material, an organic material, and an inorganic material are sequentially deposited.

In an embodiment, a touch sensor layer TSL may be disposed on the encapsulation layer TFE. The touch sensor layer TSL may include a conductive pattern for sensing a touch and an insulating layer. The conductive pattern of the touch sensor layer TSL may be formed of a single layer, or a double layer formed with an insulating layer interposed therebetween.

In an embodiment, the conductive pattern of the touch sensor layer TSL may be disposed to avoid the first emission area EA1 and the first sensor area SA1. For example, the conductive pattern of the touch sensor layer TSL may not overlap the first emission area EA1 and the first sensor area SA1, e.g., in the stacking direction of the layers.

A black matrix BM may be provided on the encapsulation layer TFE or the touch sensor layer TSL. The black matrix BM may absorb or block light incident from the outside. The black matrix BM may include an organic light blocking material. For example, the organic light blocking material may include at least one of carbon black (CB) and titanium black (TiBK), but embodiments are not limited thereto.

In an embodiment, the black matrix BM may be provided to overlap the bank layer BK. Also, the black matrix BM may be disposed to cover conductive patterns of the touch sensor layer TSL. The black matrix BM may be disposed to avoid the emission area EA. For example, the black matrix BM may not overlap the emission area EA. For example, the black matrix BM may be provided in the form of a pattern including an opening overlapping the emission area EA.

In an embodiment, the black matrix BM may be disposed to avoid the first sensor area SA1 of the first illuminance sensor LS1. For example, the opening of the black matrix BM may overlap the opening of the bank layer BK. Accordingly, the first sensor area SA1 that provides an optical path through which the external light is incident on the first illuminance sensor LS1 may be defined.

Color filters CF1 and CF2 may be disposed on the light emitting element LD and the black matrix BM. The first color filter CF1 may be one of a red color filter, a green color filter, and a blue color filter according to the color of light emitted from the emission area EA. For example, when green light is output from the first emission area EA1, the first color filter may be the green color filter.

In an embodiment, the color filters CF1 and CF2 may directly contact at least some of the top and side surfaces of the black matrix BM. For example, the color filters CF1 and CF2 may be directly disposed on the black matrix BM. Alternatively, no other material may be interposed between the color filters CF1 and CF2 and the black matrix BM except for a bonding member for bonding them.

The first color filter CF1 may selectively pass the light emitted from the light emitting element LD according to a wavelength or color. When the black matrix BM and the color filters CF1 and CF2 are disposed on a touch sensor TSL, in general, reflection of the external light may be sufficiently prevented even without a polarizing layer having a thickness of 80 μm or more. In addition, since the first color filter CF1 has a higher transmittance than that of the polarizing layer, the contrast and the light efficiency of the display panel 100 may be improved.

In an embodiment, the second color filter CF2 may be provided to overlap the first sensor area SA1 adjacent to the first emission area EA1. The second color filter CF2 may be one of a red color filter, a green color filter, and a blue color filter according to the color of light detected by the first illuminance sensor LS1. In an embodiment, the first color filter CF1 and the second color filter CF2 may be color filters of different colors.

When the second color filter CF2 is the red color filter, the first illuminance sensor LS1 may detect the amount (e.g., intensity) of red light among light incident from the outside. The second illuminance sensor LS2 may detect the amount (e.g., intensity) of light of a color different from that of the first illuminance sensor LS1. For example, the color filter disposed on the second illuminance sensor LS2 may be the blue color filter.

The black matrix BM and the color filters CF1 and CF2 may function as an antireflection layer that blocks reflection of the external light. Since the display panel 100 includes the black matrix BM and the color filters CF1 and CF2 functioning as the antireflection layer, a separate polarization layer may not be included, i.e., may be removed. Accordingly, deterioration of luminance may be prevented and the thickness of the display panel 100 may be minimized.

In addition, since the illuminance sensor LS between the pixels PX and the pixel circuit PXC are formed on the same layer (e.g., the buffer layer BF or the base layer BL), the thickness of the display panel 100 may be further reduced, and the amount (e.g., intensity) of external light incident on the illuminance sensor LS may be increased so that the performance of detecting illuminance may be improved. Furthermore, since the illuminance sensor LS and the pixel circuit PXC are simultaneously formed in the same process, the process time and the manufacturing cost of the display panel 100 may be reduced.

FIG. 5 is a circuit diagram illustrating an example of the illuminance sensor of FIG. 3.

In FIG. 5, the same reference numerals are used for the components described with reference to FIG. 3, and duplicate descriptions of these components will be omitted. In addition, the illuminance sensor LS of FIG. 5 may have a configuration substantially the same as or similar to the configuration of the illuminance sensor LS of FIG. 3 except for a light receiving element PD′.

Referring to FIG. 5, the illuminance sensor LS may include the light receiving element PD′, a sensor transistor T1, and a capacitor C1.

In an embodiment, the light receiving element PD′ may be implemented as a transistor (e.g., a phototransistor). For example, the light receiving element PD′ may have a diode-connected structure and may be connected between the second node N2 and the third power source line through which the bias power source VBIAS is transmitted. A gate electrode of the light receiving element PD′ may be connected to the second node N2.

As described above, the light receiving element PD′ may be configured with structures according to various embodiments.

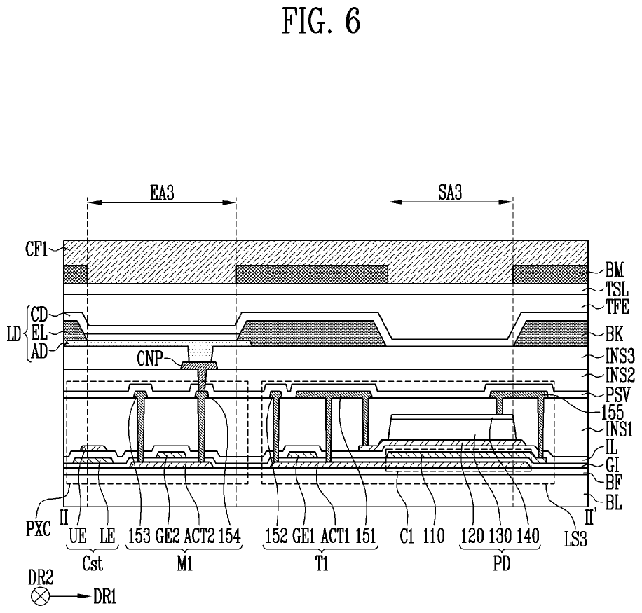

FIG. 6 is a cross-sectional view taken along lines II-II′ of FIG. 2 illustrating an example of an area of the display panel of FIG. 2.

In FIG. 6, the same reference numerals are used for the components described with reference to FIG. 4, and duplicate descriptions of these components will be omitted for descriptive convenience. In addition, the display panel of FIG. 6 may have a structure substantially the same as or similar to the structure of the display panel of FIG. 4 except for a first color filter CF1.

Referring to FIGS. 2 and 6, the light receiving element PD of a third illuminance sensor LS3 may overlap a third sensor area SA3. The color filter (e.g., the first color filter CF1) overlapping the third sensor area SA3 may be the same as the color filter (e.g., the first color filter CF1) overlapping the light emitting element (e.g., a light emitting element of a second pixel PX2) adjacent to one side of the third illuminance sensor LS3.

In an embodiment, the first color filter CF1 may be integrally formed in a third emission area EA3 and the third sensor area SA3. The first color filter CF1 may be continuously provided on the black matrix BM between the third emission area EA3 and the third sensor area SA3.

For example, when the first color filter CF1 is the green color filter, the third illuminance sensor LS3 corresponding to the third sensor area SA3 may detect the amount (e.g., intensity) of green light among the external light.

The third illuminance sensor LS3 may have substantially the same stacked structure as the first illuminance sensor LS1 and the second illuminance sensor LS2 described with reference to FIG. 4.

Each of the first illuminance sensor LS1, the second illuminance sensor LS2, and the third illuminance sensor LS3 may detect the amount (e.g., intensity) of one of red light, green light, and blue light according to the color filter corresponding thereto. The amount (e.g., intensity) of external light may be determined from a combination of detection values detected by the first illuminance sensor LS1, the second illuminance sensor LS2, and the third illuminance sensor LS3.

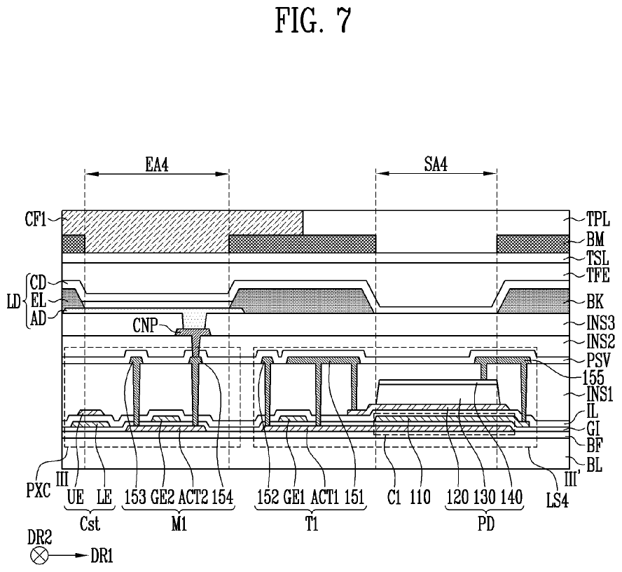

FIG. 7 is a cross-sectional view taken along lines III-III′ of FIG. 2 illustrating an example of an area of the display panel of FIG. 2.

In FIG. 7, the same reference numerals are used for the components described with reference to FIG. 4, and duplicate descriptions of these components will be omitted for descriptive convenience. In addition, the display panel of FIG. 7 may have a structure substantially the same as or similar to the structure of the display panel of FIG. 4 except for a transparent insulating layer TPL.

Referring to FIGS. 2 and 7, the light receiving element PD of the fourth illuminance sensor LS4 may overlap a fourth sensor area SA4.

The fourth illuminance sensor LS4 may be disposed adjacent to a predetermined pixel PX (e.g., the second pixel PX2) corresponding to a fourth emission area EA4 in the first direction DR1.

In an embodiment, the transparent insulating layer TPL may be disposed on the encapsulation layer TFE or the touch sensor layer TSL so as to overlap the fourth sensor area SA4 and the light receiving element PD of the fourth illuminance sensor LS4. The transparent insulating layer TPL may cover a portion of the black matrix BM adjacent to the fourth sensor area SA4.

In an embodiment, the transparent insulating layer TPL may include a transparent organic insulating material and/or a transparent inorganic insulating material.

A white light component of the external light may be provided to the light receiving element PD by the transparent insulating layer TPL. The fourth illuminance sensor LS4 may generate a detection value corresponding to the amount (e.g., intensity) of white light. The detection value of the white light may be provided as a white reference for detection values of the first, second, and third illuminance sensors LS1, LS2, and LS3. Accordingly, reliability of the detected illuminance may be improved.

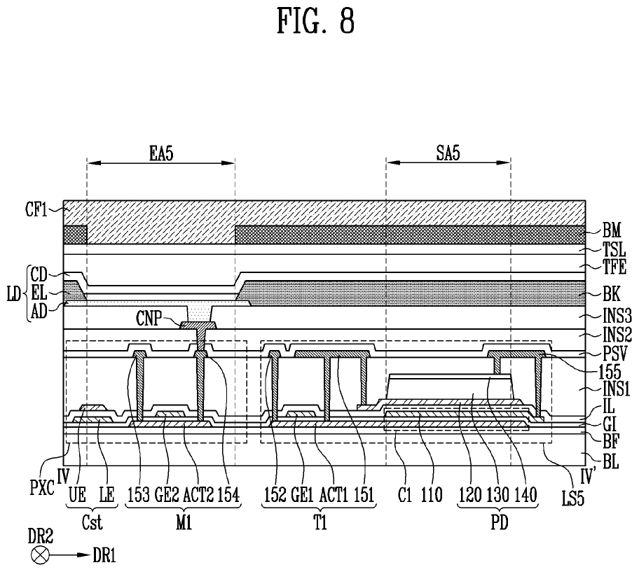

FIG. 8 is a cross-sectional view taken along lines IV-IV′ of FIG. 2 illustrating an example of an area of the display panel of FIG. 2.

In FIG. 8, the same reference numerals are used for the components described with reference to FIG. 4, and duplicate descriptions of these components will be omitted for descriptive convenience. In addition, the display panel of FIG. 8 may have a structure substantially the same as or similar to the structure of the display panel of FIG. 4 except for the stacked structure of a fifth sensor area SA5.

Referring to FIGS. 2, 7 and 8, the light receiving element PD of the fifth illuminance sensor LS5 may overlap the fifth sensor area SA5.

The fifth illuminance sensor LS5 may be disposed adjacent to a predetermined pixel PX (e.g., the second pixel PX2) corresponding to a fifth emission area EA5 in the first direction DR1.

In an embodiment, the black matrix BM and the bank layer BK may extend to overlap the light receiving element PD of the fifth illuminance sensor LS5 and the fifth sensor area SA5. Accordingly, the external light incident on the light receiving element PD may be blocked. The dark current may be generated in the fifth illuminance sensor LS5. This is a dark reference and may be applied to the detection values of the first, second, and third illuminance sensors LS1, LS2, and LS3. Accordingly, the reliability of the detected illuminance may be further improved.

As described above, in order to detect the external light of the fourth and fifth illuminance sensors LS4 and LS5 for the white reference and the dark reference, the transparent insulating layer TPL may be disposed in the fourth sensor area SA4 to replace the color filter, and the bank layer BK and the black matrix BM may be provided in the fifth sensor area SA5.

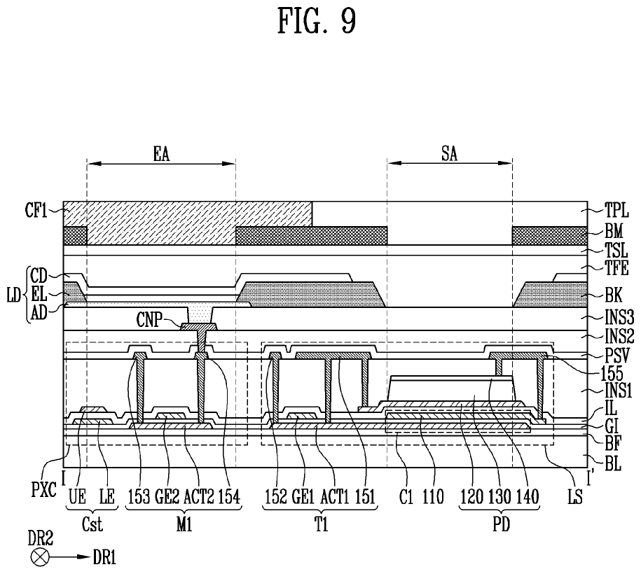

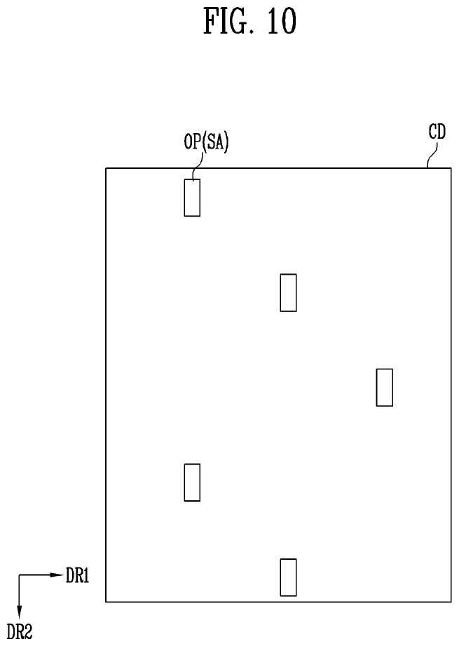

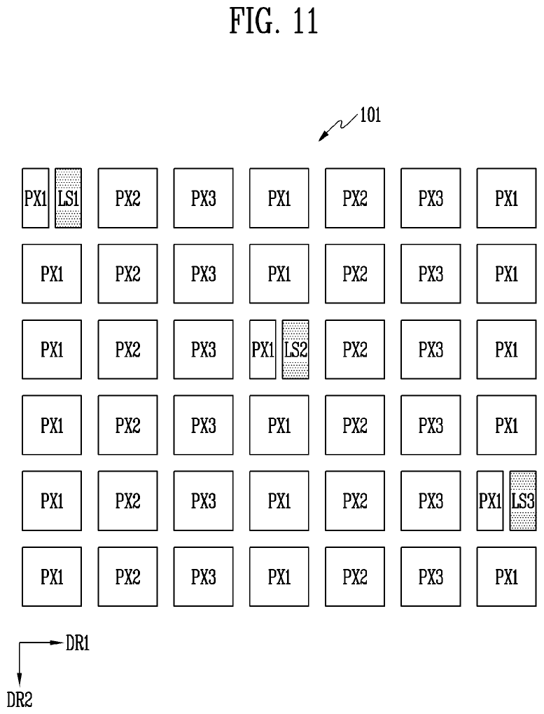

FIG. 9 is a cross-sectional view taken along lines I-I′ of FIG. 2 illustrating another example of an area of the display panel of FIG. 2. FIG. 10 is a plan view illustrating an example of a second electrode of a light emitting element included in the display panel of FIG. 9.

In FIGS. 9 and 10, the same reference numerals are used for the components described with reference to FIG. 4, and duplicate descriptions of these components will be omitted for descriptive convenience. In addition, the display panel of FIG. 9 may have a structure substantially the same as or similar to the structure of the display panel of FIG. 4 except for the second electrode of the light emitting element LD.

Referring to FIGS. 9 and 10, a light emitting element LD may include a first electrode AD, a light emitting layer EL, and a second electrode CD that are sequentially stacked.

In an embodiment, the second electrode CD may include an opening OP overlapping the sensor area SA. The second electrode CD may be patterned to expose the third insulating layer INS3 corresponding to the sensor area SA. For example, as shown in FIG. 10, the second electrode CD may have a pattern including openings OP corresponding to sensor areas SA (e.g., SA1, SA3, SA4, and SA5).

Accordingly, the amount (e.g., intensity) of external light incident on the illuminance sensor LS may be increased.

FIG. 11 is a diagram conceptually illustrating an example of the display panel included in the display device of FIG. 1.

Referring to FIGS. 1 and 11, a display panel 101 may include a plurality of pixels PX1, PX2, and PX3 and a plurality of illuminance sensors LS1, LS2, and LS3.

The first pixel PX1, the second pixel PX2, and the third pixel PX3 may emit a first color light, a second color light, and a third color light, respectively. In an embodiment, the first color light, the second color light, and the third color light may be different color lights, and may be one of red light, green light, and blue light. For example, the pixels PX1, PX2, and PX3 may be arranged in the first direction DR1 in the order of a red pixel, a green pixel, and a blue pixel for each pixel row to form, e.g., an RGB pixel structure. However, this is an example, and embodiments are not limited to the arrangement structure of the pixels.

For example, in FIG. 11, except for portions in which the illuminance sensors LS1, LS2, and LS3 are disposed, the first, second, and third pixels PX1, PX2, and PX3 are shown as having the same area, but embodiments are not limited thereto. For example, a pixel emitting blue light may have a larger area than other pixels. In the embodiments, the size (e.g., area) of a pixel may be understood as an area of an emission area of the corresponding pixel.

In an embodiment, when viewed on a plane, each of the illuminance sensors LS1, LS2, and LS3 may be disposed between predetermined pixels. For example, each of the illuminance sensors LS1, LS2, and LS3 may be disposed on one side of each of the predetermined first pixels PX1. Here, in order to minimize the deterioration of image quality, the number of illuminance sensors may be smaller than the number of pixels. However, this is an example, and the position and the number of the illuminance sensors LS1, LS2, and LS3 are not limited to the structure shown in FIG. 11.

In addition, although only the first, second, and third illuminance sensors LS1, LS2, and LS3 are shown in FIG. 11, the fourth and fifth illuminance sensors LS4 and LS5 described with reference to FIGS. 7 and 8 may be further included.

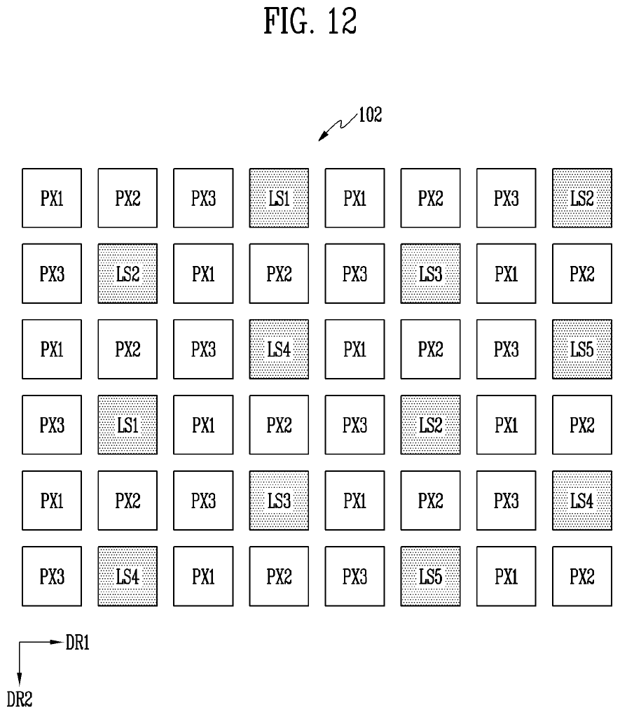

FIG. 12 is a diagram conceptually illustrating an example of the display panel included in the display device of FIG. 1.

Referring to FIGS. 1 and 12, a display panel 102 may include a plurality of pixels PX1, PX2, and PX3 and a plurality of illuminance sensors LS1, LS2, LS3, LS4, and LS5.

In an embodiment, in the first pixel row (e.g., odd pixel rows) controlled by the first scan line, the pixels PX1, PX2, and PX3 may be arranged in the order of a red pixel, a green pixel, and a blue pixel in the first direction DR1. In the second pixel row (e.g., even pixel rows) controlled by the second scan line, the pixels PX1, PX2, and PX3 may be arranged in the order of a blue pixel, a green pixel, and a red pixel in the first direction DR1. The pixel arrangement of the first pixel row and the pixel arrangement of the second pixel row may be alternately repeated in the second direction DR2.

In an embodiment, the illuminance sensors LS1, LS2, LS3, LS4, and LS5 may be provided between a predetermined third pixel PX3 and a predetermined first pixel PX1 in the first direction DR1, respectively. In addition, a size (e.g., area) of the sensor area SA corresponding to the illuminance sensors LS1, LS2, LS3, LS4, and LS5 may be provided at a level similar to a size (e.g., area) of other pixels PX1, PX2, and PX3 adjacent thereto. In addition, the illuminance sensors LS1, LS2, LS3, LS4, and LS5 of FIG. 12 may be arranged more densely than the illuminance sensors LS1, LS2, and LS3 of FIG. 11. Accordingly, reliability of the illuminance detection result may be improved.

However, this is an example, and the arrangement structure of the pixels PX1, PX2, and PX3 and the position, the size (e.g., area), and the number of the illuminance sensors LS1, LS2, LS3, LS4, and LS5 are not limited thereto, and may be variously modified according to the purpose and design of the display device 1000.

As described above, the display panel according to the embodiments may include the black matrix and the color filters functioning as the antireflection layer. Therefore, a separate polarization layer may be removed. Accordingly, deterioration of luminance may be prevented and the thickness of the display panel may be minimized.

In addition, since the illuminance sensor is formed on the same layer as the pixel circuit between the pixels, the thickness of the display device may be further reduced, and the amount (e.g., intensity) of external light incident on the illuminance sensor may be increased so that the reliability of detecting illuminance may be improved. Furthermore, since the illuminance sensor is simultaneously formed in the same process as the pixel circuit, the process time and manufacturing cost may be reduced.

Although certain exemplary embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display panel comprising:
a base layer comprising an emission area and a sensor area;
a pixel circuit disposed on the base layer;
illuminance sensors disposed on the sensor area of the base layer, each of the illuminance sensors comprising a light receiving element overlapping the sensor area, the light receiving element disposed to be adjacent to the pixel circuit;
light emitting elements disposed on the pixel circuit, each of the light emitting elements comprising a light emitting layer overlapping the emission area;
a black matrix disposed on the light emitting element, the black matrix comprising openings overlapping the light emitting layer; and
a color filter disposed on the light emitting elements and the black matrix.

2. The display panel of claim 1, wherein each of the illuminance sensors further comprises:
a sensor transistor connected to the light receiving element; and
a capacitor connected to the light receiving element and configured to store a detection value of the light receiving element.

3. The display panel of claim 2, wherein the sensor transistor comprises:
a first active pattern disposed on the base layer;
a first gate electrode overlapping the first active pattern and disposed on a gate insulating layer covering the first active pattern; and
a first source electrode and a first drain electrode disposed on an interlayer insulating layer covering the first gate electrode and a first insulating layer, and contacting the first active pattern through contact holes penetrating the first insulating layer, the interlayer insulating layer, and the gate insulating layer.

4. The display panel of claim 3, wherein the pixel circuit further comprises:
a pixel transistor connected to each of the light emitting elements, and
wherein the pixel transistor comprises:
a second active pattern disposed on a same layer, on which the first active pattern is disposed;
a second gate electrode disposed on a same layer, on which the first gate electrode disposed; and
a second source electrode and a second drain electrode disposed on a same layer, on which the first source electrode is disposed, and contacting the second active pattern through contact holes penetrating the first insulating layer, the interlayer insulating layer, and the gate insulating layer.

5. The display panel of claim 3, wherein each of the light emitting elements further comprises a first electrode and a second electrode disposed on a second insulating layer on the pixel circuit,
wherein the light emitting layer is interposed between the first electrode and the second electrode.

6. The display panel of claim 5, further comprising a bank layer disposed on the second insulating layer to expose an upper surface of the first electrode, the bank layer partitioning the emission area.

7. The display panel of claim 6, wherein the bank layer overlaps the black matrix and is disposed between the emission area and the sensor area in a plan view.

8. The display panel of claim 6, wherein:
the color filter comprises a first color filter overlapping a light receiving element of a first illuminance sensor among the illuminance sensors and a second color filter overlapping a first light emitting element among the light emitting elements, the first light emitting element adjacent to one side of the first illuminance sensor in a first direction, and
the first color filter is different from the second color filter.

9. The display panel of claim 8, wherein:
the color filter further comprises a third color filter overlapping a light receiving element of a second illuminance sensor among the illuminance sensors and a fourth color filter overlapping a second light emitting element among the light emitting elements, the second light emitting element adjacent to one side of the second illuminance sensor in the first direction, and
the third color filter is same as the fourth color filter.

10. The display panel of claim 9, further comprising a transparent insulating layer overlapping a light receiving element of a third illuminance sensor among the illuminance sensors and covering a portion of the black matrix.

11. The display panel of claim 9, wherein the black matrix and the bank layer overlap a light receiving element of a fourth illuminance sensor among the illuminance sensors.

12. The display panel of claim 8, wherein a size of the emission area corresponding to the first light emitting element is smaller than a size of the emission area corresponding to a light emitting element that emits light in a same color as that of light emitted by the first light emitting element and is not adjacent to the illuminance sensors.

13. The display panel of claim 8, wherein the pixel circuit connected to the first light emitting element and the first illuminance sensor are connected to a same scan line.

14. The display panel of claim 5, wherein the second electrode extends to overlap the sensor area.

15. The display panel of claim 5, wherein the second electrode comprises an opening overlapping the sensor area.

16. The display panel of claim 3, wherein the light receiving element comprises:
a conductive layer disposed on the interlayer insulating layer;
a semiconductor layer disposed on the conductive layer; and
a transparent conductive layer disposed on the semiconductor layer and overlapping the sensor area.

17. The display panel of claim 16, wherein each of the illuminance sensors further comprises a bias electrode disposed on the first insulating layer, the bias electrode connected to the transparent conductive layer by passing through the first insulating layer.

18. The display panel of claim 17, wherein the capacitor comprises a capacitor electrode pattern disposed on a same layer, on which the first gate electrode is disposed, and overlapping the first active pattern.

19. The display panel of claim 18, wherein the bias electrode passes through the interlayer insulating layer and the first insulating layer, and is connected to the capacitor electrode pattern.

20. The display panel of claim 1, further comprising a touch sensor layer disposed between the light emitting elements and the black matrix.
